(19) United States
(12) Patent Application Publication
(10) Pub. No.: US 2026/0075961 A1
(43) Pub. Date: Mar. 12, 2026

(54) ELECTRONIC DEVICE

(71) Applicant: InnoCare Optoelectronics Corporation, Tainan City (TW)

(72) Inventors: Hsin-Hung Lin, Tainan City (TW); Sheng-I Chen, Tainan City (TW)

(73) Assignee: InnoCare Optoelectronics Corporation, Tainan City (TW)

(21) Appl. No.: 19/290,343

(22) Filed: Aug. 4, 2025

(30) Foreign Application Priority Data
Sep. 11, 2024 (TW) 113134427

(51) Int. Cl. H10D 89/60; H10D 30/67

(52) U.S. Cl. CPC H10D 89/811; H10D 30/6729; H10D 30/6731; H10D 30/6732; H10D 89/931

(57) ABSTRACT

An electronic device includes a scan line, an active element, an internal short-circuit ring, an electrostatic protection element. The active element is disposed in an active area and electrically connected to the scan line. The internal short-circuit ring is disposed in a peripheral area and surrounds the active area. The electrostatic protection element is disposed in the peripheral area and electrically connected to the internal short-circuit ring and the scan line. The electrostatic protection element is a transistor and includes a gate electrode, first and second source/drain electrodes, and a semiconductor layer. The gate electrode is in a floating state, the first source/drain electrode is coupled to the internal short-circuit ring, the second source/drain electrode is coupled to the scan line. A first parasitic capacitance between the gate electrode and the first source/drain electrode is greater than a second parasitic capacitance between the gate electrode and the second source/drain electrode.

### CROSS-REFERENCE TO RELATED APPLICATION

This application claims the priority benefit of Taiwan application serial no. 113134427, filed on September 11, 2024. The entirety of the above-mentioned patent application is hereby incorporated by reference herein and made a part of this specification.

### TECHNICAL FIELD

The disclosure relates to an electronic device, and in particular to an electronic device including an electrostatic protection element.

### DESCRIPTION OF RELATED ART

Electrostatic discharge (ESD) is one of the main factors that cause failure or damage of most electronic devices. Therefore, in order to reduce the damage caused by electrostatic discharge to electronic elements in the electronic devices, the electronic elements in the active area are coupled to an electrostatic protection circuit via a scan line or other circuits.

The electrostatic protection circuit includes an electrostatic protection element and a circuit coupled thereto, wherein a common electrostatic protection element is a back-to-back diode, and the circuit is, for example, an internal short-circuit ring. However, when an operating voltage is applied to a specific scan line for operating an electronic element in the active area, the difference between the operating voltage and the voltage applied to the internal short-circuit ring is increased, thus increasing the leakage current of the electrostatic protection element flowing to the internal short-circuit ring and affecting the reliability of the electronic device.

### SUMMARY

Some embodiments of the disclosure are directed to an electronic device having relatively high reliability.

According to some embodiments of the disclosure, an electronic device is provided, including a scan line, an active element, an internal short-circuit ring, and an electrostatic protection element. The active element is disposed in an active area and electrically connected to the scan line. The internal short-circuit ring is disposed in a peripheral area and surrounds the active area. The electrostatic protection element is disposed in the peripheral area and electrically connected to the internal short-circuit ring and the scan line. The electrostatic protection element is a transistor and includes a gate electrode, a first source/drain electrode, a second source/drain electrode, and a semiconductor layer. The gate electrode is in a floating state, the first source/drain electrode is coupled to the internal short-circuit ring, and the second source/drain electrode is coupled to the scan line. A first parasitic capacitance between the gate electrode and the first source/drain electrode is greater than a second parasitic capacitance between the gate electrode and the second source/drain electrode.

Accordingly, in the electronic device provided in some embodiments of the disclosure, the parasitic capacitance between the gate electrode and the first source/drain electrode of the electrostatic protection element included therein is greater than the parasitic capacitance between the gate electrode and the second source/drain electrode. Via this design, when an operating voltage is applied to a specific scan line, the voltage of the gate electrode is relatively close to the voltage applied to the internal short-circuit ring, thereby reducing the leakage current of the electrostatic protection element flowing to the internal short-circuit ring, thereby improving the reliability of the electronic device provided by some embodiments of the disclosure.

In order to make the aforementioned features and advantages of the disclosure more comprehensible, embodiments accompanied with figures are described in detail below.

### BRIEF DESCRIPTION OF THE DRAWINGS

FIG. 1A is a partial top view of an electronic device of an embodiment of the disclosure.

FIG. 1B is a circuit diagram of an electrostatic protection element in an electronic device of an embodiment of the disclosure.

FIGS. 2A to 2T are partial top views of electrostatic protection elements in electronic devices of a plurality of embodiments of the disclosure.

### DESCRIPTION OF THE EMBODIMENTS

The disclosure may be understood by referring to the following detailed description in combination with the accompanying drawings. It should be noted that in order to make it easy for readers to understand and for the simplicity of the drawings, many of the drawings in the disclosure depict portions of the electronic device, and certain elements in the drawings are not drawn to actual scale. In addition, the number and the size of elements in the figures are for illustration and are not intended to limit the scope of the disclosure.

Throughout the disclosure, certain words are used to refer to specific elements in the specification and the claims. Those skilled in the art should understand that electronic device manufacturers may refer to the same elements by different names. The specification does not intend to distinguish between elements having the same function but different names. In the specification below and the claims, words such as “include”, “contains”, and “have” are open-ended words, so they should be interpreted to mean “containing but not limited to...” Therefore, when the terms “including”, “containing”, and/or “having” are used in the specification of the disclosure, they specify the presence of the corresponding features, areas, steps, operations, and/or members. However, the presence of one or a plurality of corresponding features, areas, steps, operations, and/or members is not excluded.

The directional terms mentioned herein, such as “upper”, “lower”, “front”, “rear”, “left”, “right”, etc., refer to the directions of the drawings. Accordingly, the directional terms used are illustrative, not limiting, of the disclosure. In the drawings, each drawing depicts general features of methods, structures, and/or materials used in specific embodiments. However, the drawings should not be interpreted as defining or limiting the scope or the nature encompassed by the embodiments. For example, the relative sizes, the thicknesses, and the locations of various layers, regions, and/or structures may be reduced or exaggerated for clarity.

When a corresponding member (such as a layer or an area) is referred to as being “on another member”, the corresponding member may be directly on the another member, or other members may be present between the two members. Moreover, when a member is referred to as being “directly on another member”, there are no intervening members between the two members. In addition, when a member is referred to as “on another member”, the two members have a top-down relationship in the top view direction, and the member may be above or below the another member, and the relationship depends on the orientation of the device.

The terms “about”, “equal to”, “equal” or “same”, “substantially” or “essentially” are generally interpreted as within 20% of the given value or range, or interpreted as within 10%, 5%, 3%, 2%, 1%, or 0.5% of a given value or range. Moreover, the phrases “a given range is between a first value and a second value”, “a given range falls within the range from a first value to a second value” mean that the given range includes the first value, the second value, and other values therebetween.

Words such as “first” and “second” used in the specification and claims are used to modify elements, which do not themselves imply and represent that the (or these) elements have any previous ordinal numbers, nor do they imply an order of a certain element with another element, or an order in manufacturing methods. These ordinal numbers are used to clearly distinguish an element having a certain designation from another element having the same designation. The same wording may be not used in the claims and the specification. Accordingly, the first member in the specification may be the second member in the claims.

It should be noted that, in the following embodiments, without departing from the spirit of the disclosure, features in several different embodiments may be replaced, reorganized, and mixed to complete other embodiments. As long as the features of the various embodiments do not violate the spirit of the disclosure or conflict each other, they may be mixed and matched arbitrarily.

The electrical connection or coupling described in the disclosure may both refer to direct connection or indirect connection. In the case of a direct connection, the terminals of elements on two circuits are connected directly or to each other by a conductor segment. In the case of indirect connection, there are switches, diodes, capacitors, inductors, other suitable elements, or a combination of the above elements between the terminals of the elements on the two circuits, but the disclosure is not limited thereto.

In the disclosure, the thickness, the length, and the width may be measured using an optical microscope, and the thickness may be measured using a cross-sectional image in an electron microscope, but the disclosure is not limited thereto. In addition, any two values or directions used for comparison may have certain errors. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

An electronic device of the disclosure may include a detection device, a display device, an antenna device (such as a liquid-crystal antenna), a light-emitting touch device, a tiling device, a device having other suitable functions, or a combination of devices having the above functions, but the disclosure is not limited thereto. The electronic device includes a rollable or flexible electronic device, but the disclosure is not limited thereto. The electronic device may include, for example, liquid crystal, light-emitting diode (LED), photodiode, quantum dot (QD), fluorescence, phosphor, other suitable materials, or a combination thereof. The electronic device may include an electronic element. The electronic element may include a passive element and an active element, such as a capacitor, a resistor, an inductor, a diode, a transistor, etc. The diode may include a light-emitting diode or a photodiode. The light-emitting diode may include, for example, an organic light-emitting diode (OLED), a sub-millimeter light-emitting diode (mini LED), a micro light-emitting diode (micro LED), or a quantum dot light-emitting diode (quantum dot, QD, which may be, for example, QLED, QDLED) or other suitable materials or any combination of the above materials, but the disclosure is not limited thereto. It should be noted that the electronic device may be any arrangement and combination of the above, but the disclosure is not limited thereto. In addition, the shape of the electronic device may be rectangular, circular, polygonal, a shape having curved edges, or other suitable shapes. The electronic device may have a peripheral system such as a driving system, a control system, a light source system, a shelf system, etc. to support the display device or the tiling device. It should be noted that the electronic device may be any arrangement and combination of the above, but the disclosure is not limited thereto. The electronic device may include a plurality of components, and at least two components may be assembled to form a composite object. The following description adopts a detection panel as an electronic device to illustrate the disclosure, but the disclosure is not limited thereto.

Exemplary embodiments of the disclosure are described below, and the same reference numerals are used in the drawings and description to indicate the same or similar portions.

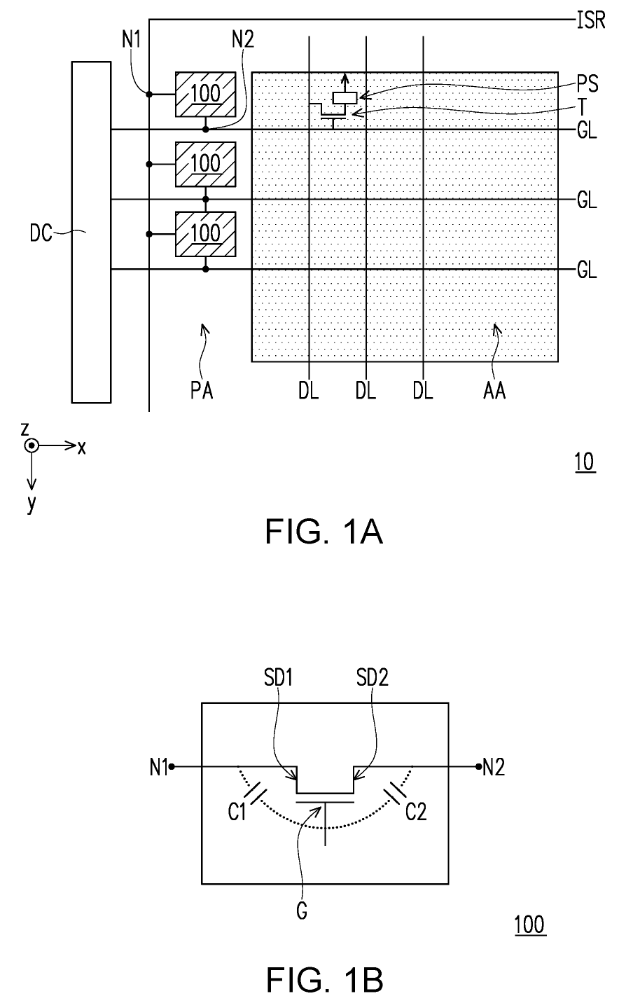

FIG. 1A is a partial top view of an electronic device of an embodiment of the disclosure, and FIG. 1B is a circuit diagram of an electrostatic protection element in an electronic device of an embodiment of the disclosure.

Referring to FIG. 1A, an electronic device 10 of the present embodiment has an active area AA. In some embodiments, the active area AA of the electronic device 10 may include an active element T and a photosensitive element PS. The active element T is, for example, coupled to the photosensitive element PS. The active element T may be, for example, a bottom-gate thin-film transistor, a top-gate thin-film transistor, or other thin-film transistors known to those having ordinary skill in the art, but the disclosure is not limited thereto. The photosensitive element PS can, for example, receive light and generate carriers (such as electrons and/or electron holes). When the active element T is not turned on, the carriers are stored in the photosensitive element PS. When the active device T is turned on, the carriers stored in the photosensitive element PS may be transmitted to a processing circuit (not shown) via a data line DL to be described later, thereby achieving the object of light sensing. However, the disclosure is not limited thereto. In other embodiments, the active area AA of the electronic device 10 may include the active element T, a storage capacitor (not shown), or other electronic elements.

In the present embodiment, the electronic device 10 includes a scan line GL, a data line DL, a gate driving circuit DC, an internal short-circuit ring ISR, and an electrostatic protection element 100.

The scan line GL is, for example, coupled to the gate terminal of the active device T in the active area AA, and may be used, for example, to provide a scan signal to the corresponding active element T to turn the corresponding active element T on. In some embodiments, the scan line GL is extended in a direction x, but the disclosure is not limited thereto.

The data line DL is, for example, coupled to the drain terminal of the active element T in the active area AA, and may be used to receive a signal (sensing current) generated by the photosensitive element PS, and the data line DL may transmit the sensing current to a processing circuit (not shown). For example, the processing circuit may convert the sensing current into a sensing voltage and determine the intensity of the light received by the electronic device 10, but the disclosure is not limited thereto. In some embodiments, the data line DL is extended in a direction y, wherein the direction y may be perpendicular to the direction x, but the disclosure is not limited thereto.

The gate driving circuit DC is, for example, disposed in a peripheral area PA of the electronic device 10 and is, for example, electrically connected to the scan line GL. In the present embodiment, the peripheral area PA is an area outside the active area AA, but the disclosure is not limited thereto. In some embodiments, the gate driving circuit DC may transmit the corresponding gate signal to the active element T via the scan line GL.

The internal short-circuit ring ISR is, for example, disposed in the peripheral area PA. In the present embodiment, the internal short-circuit ring ISR surrounds the active area AA and is electrically connected to the electrostatic protection element 100. Accordingly, when an excessively high voltage pulse is to be transmitted to a specific signal line, the internal short-circuit ring ISR may form one relatively low impedance current path with the electrostatic protection element 100 to reduce the instantaneous current entering the active area AA, thereby reducing the possibility of damage to the active element T, the photosensitive element PS, and/or other electronic elements inside the active area AA.

The electrostatic protection element 100 is, for example, disposed in the peripheral area PA and, for example, electrically connected to the internal short-circuit ring ISR and the scan line GL. In the present embodiment, the electrostatic protection element 100 is a transistor. In detail, the electrostatic protection element 100 includes a gate electrode G, a source/drain electrode SD1, a source/drain electrode SD2, and a semiconductor layer (not shown). The gate electrode G is not connected to an external voltage during operation, for example. That is, the gate electrode G is in a floating state. The source/drain electrode SD1 is, for example, electrically connected to the internal short-circuit ring ISR, and the source/drain electrode SD2 is, for example, electrically connected to the scan line GL. Specifically, in the present embodiment, the source/drain electrode SD1 and the internal short-circuit ring ISR are coupled to a node N1, and the source/drain electrode SD2 and the scan line GL are coupled to a node N2.

In the present embodiment, a parasitic capacitance C1 between the gate electrode G and the source/drain electrode SD1 is designed to be greater than a parasitic capacitance C2 between the gate electrode G and the source/drain electrode SD2. In some embodiments, the parasitic capacitance C1 and the parasitic capacitance C2 satisfy the following inequality: 1<C1/C2<4. In some other embodiments, the parasitic capacitance C1 and the parasitic capacitance C2 satisfy the following inequality: 1.5<C1/C2<2.5. Via this design, when an operating voltage is applied to a specific scan line GL, the voltage value of the gate electrode G is relatively close to the voltage (the voltage value of the node N1) applied to the internal short-circuit ring ISR, thereby reducing the leakage current of the electrostatic protection element 100 flowing to the internal short-circuit ring ISR.

The parasitic capacitance C1 (the parasitic capacitance C2) between the gate electrode G and the source/drain electrode SD1 (the source/drain electrode SD2) may be designed by adjusting the overlap area between the gate electrode G and the source/drain electrode SD1 (the source/drain electrode SD2). Specifically, as the overlap area between the gate electrode G and the source/drain electrode SD1 (the source/drain electrode SD2) is increased, the parasitic capacitance C1 (the parasitic capacitance C2) between the gate electrode G and the source/drain electrode SD1 (the source/drain electrode SD2) is also increased. Therefore, in the embodiments of each electrostatic protection element 100 to be introduced below, the overlap area of the gate electrode G and the source/drain electrode SD1 in a normal direction z of the active area AA is designed to be greater than the overlap area of the gate electrode G and the source/drain electrode SD2 in the normal direction z of the active area AA.

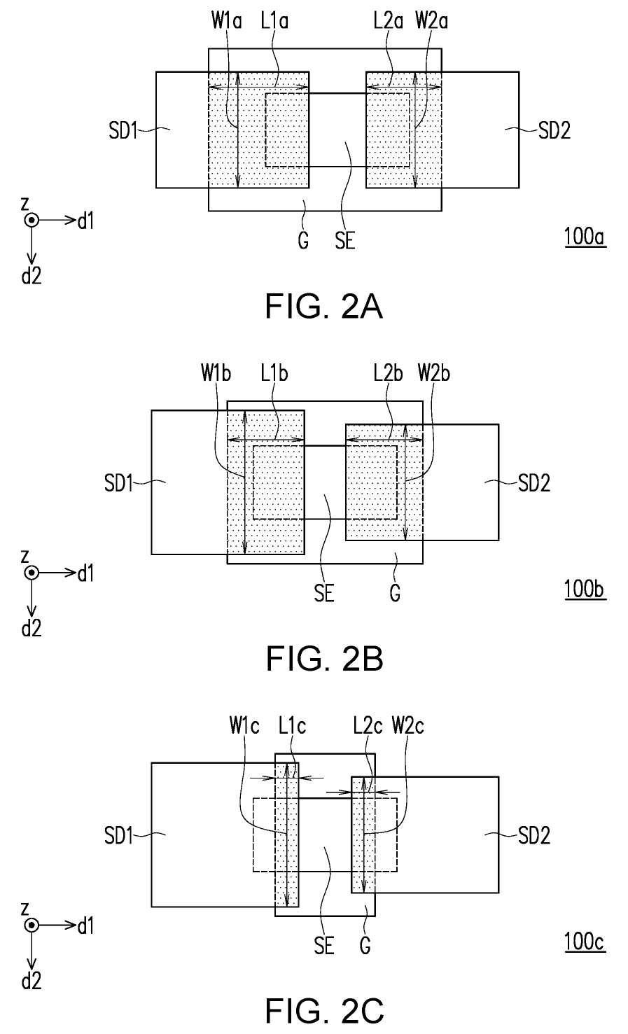

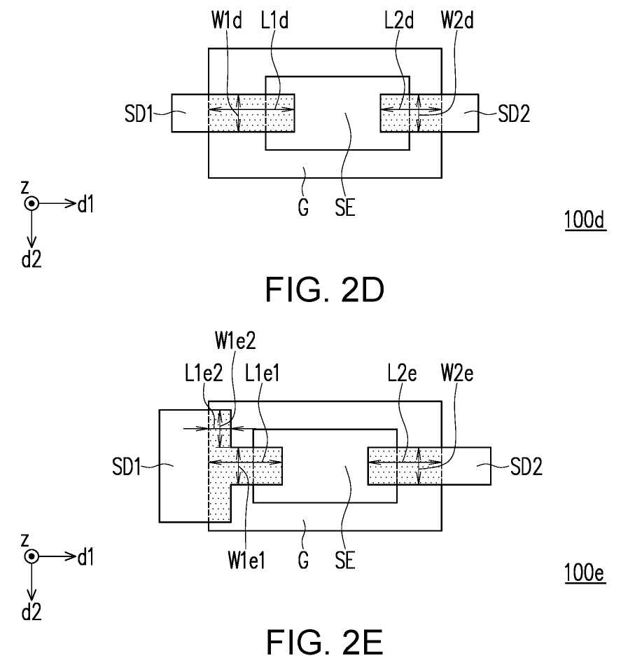

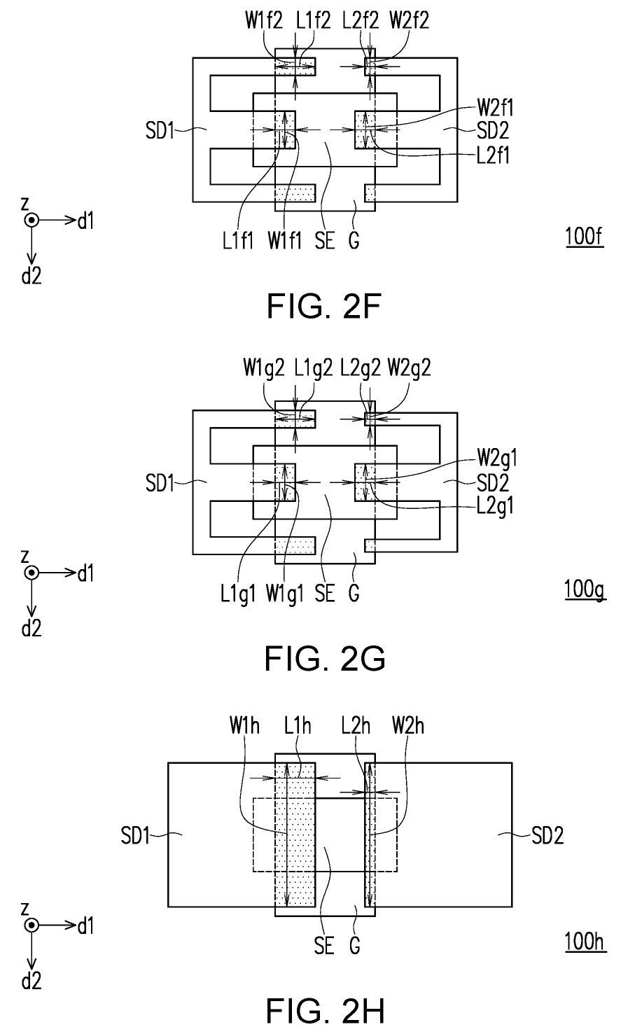

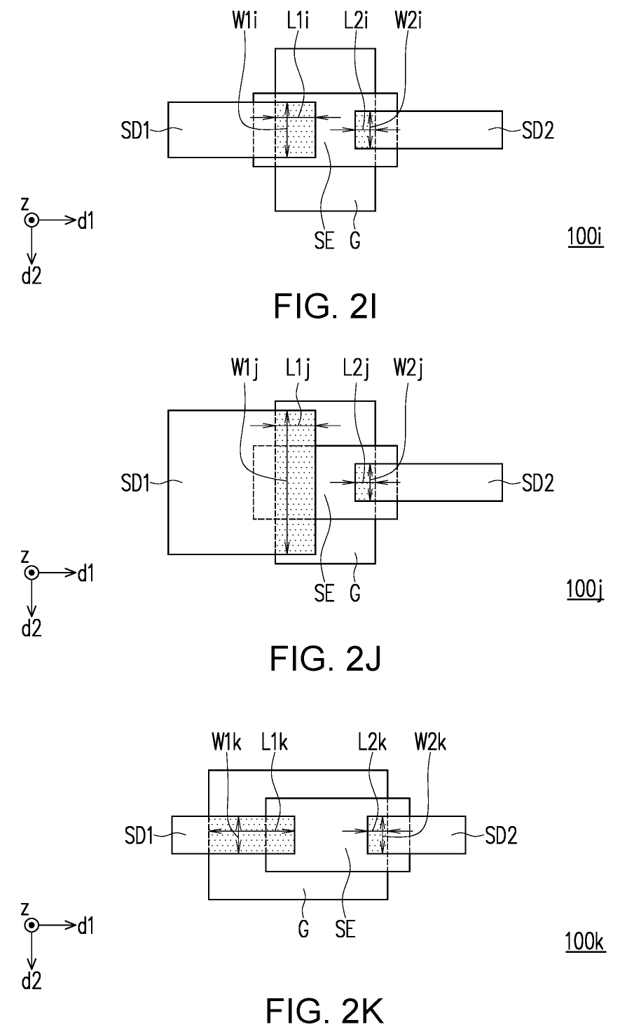

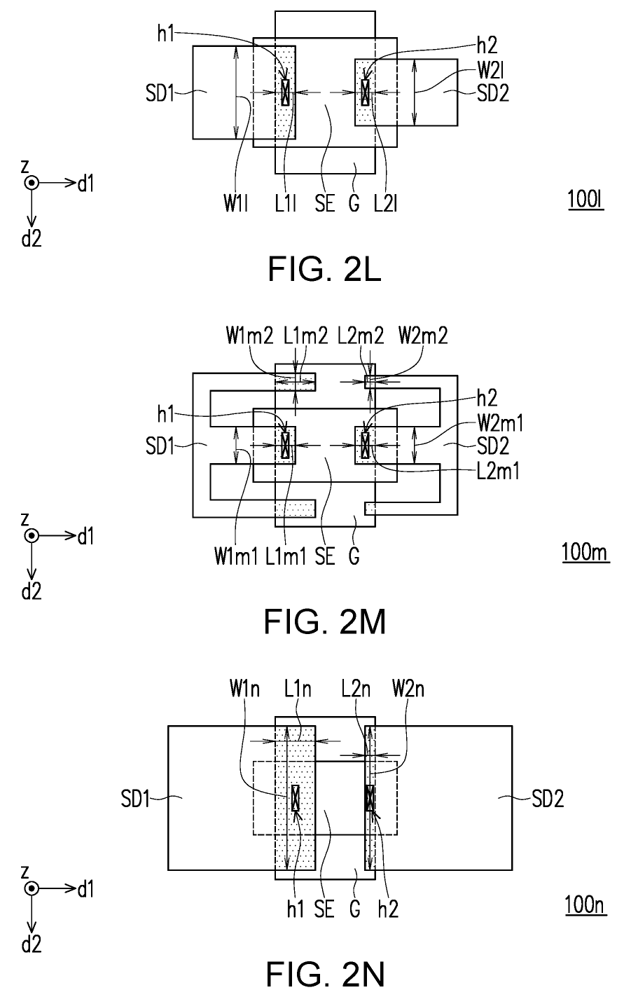

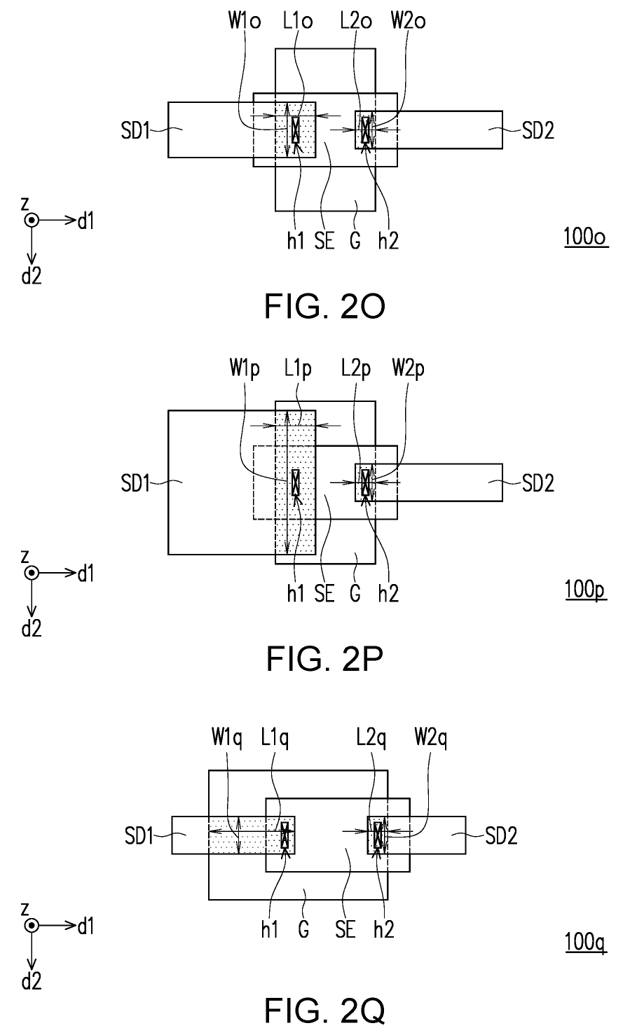

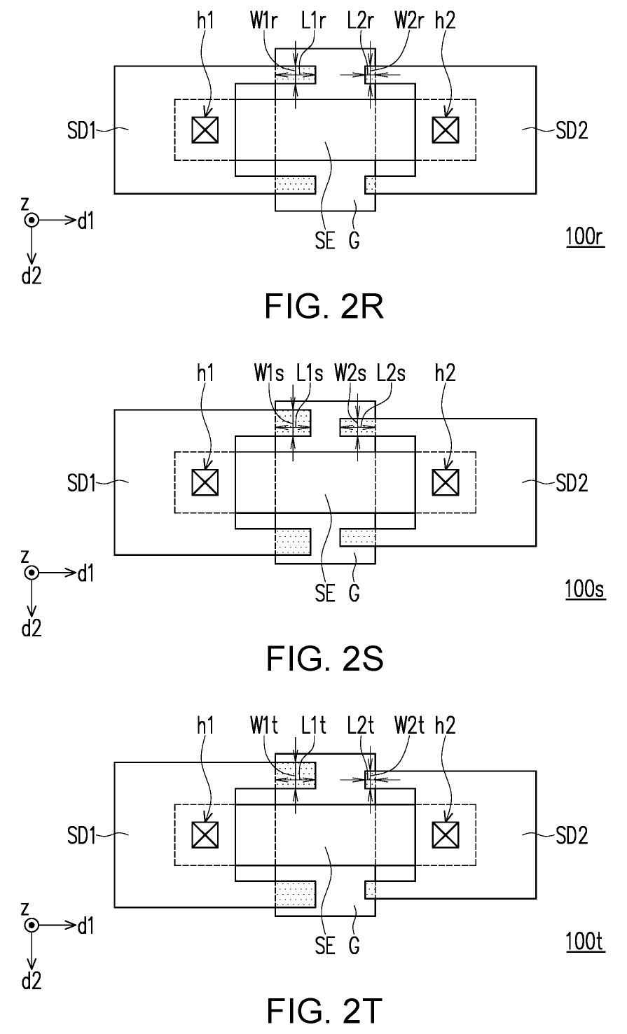

The structure of the electrostatic protection device 100 of each embodiment is briefly described below with reference to FIG. 2A to FIG. 2T, but the disclosure is not limited thereto.

Referring to FIG. 2A, an electrostatic protection device 100a of the present embodiment is a bottom-gate thin-film transistor including the gate electrode G, the source/drain electrode SD1, the source/drain electrode SD2, and the semiconductor layer SE. The gate electrode G is partially overlapped with the semiconductor layer SE in the normal direction z of the active area AA, for example, wherein the overlap area of the semiconductor layer SE and the gate electrode G may be regarded as a channel area. The source/drain electrode SD1 and the source/drain electrode SD2 are, for example, separated from each other and respectively electrically connected to the semiconductor layer SE. In some embodiments, the material of the semiconductor layer SE may include amorphous silicon, low-temperature polycrystalline silicon (LTPS), metal oxide, other suitable materials, or a combination thereof, wherein the metal oxide may include indium gallium zinc oxide (IGZO), but the disclosure is not limited thereto.

The gate electrode G is partially overlapped with the source/drain electrode SD1 and the source/drain electrode SD2 in the normal direction z of the active area AA. In the present embodiment, the overlap area of the gate electrode G and the source/drain electrode SD1 and the overlap area between the gate electrode G and the source/drain electrode SD2 have a rectangular pattern in the normal direction z of the active area AA, but the disclosure is not limited thereto.

Specifically, the overlap area of the gate electrode G and the source/drain electrode SD1 has a length L1a in a direction d1, and the overlap area of the gate electrode G and the source/drain electrode SD1 has a width W1a in a direction d2. Moreover, the overlap area of the gate electrode G and the source/drain electrode SD2 has a length L2a in the direction d1, and the overlap area of the gate electrode G and the source/drain electrode SD2 has a width W2a in the direction d2. In the present embodiment, the direction d1 is perpendicular to the direction d2, and the direction d1 and the direction d2 are respectively perpendicular to the normal direction z of the active area AA.

In the present embodiment, the length L1a is greater than the length L2a, and the width W1a is substantially equal to the width W2a. Accordingly, the overlap area of the gate electrode G and the source/drain electrode SD1 in the normal direction z of the active area AA is greater than the overlap area of the gate electrode G and the source/drain electrode SD2 in the normal direction z of the active area AA. As described in the above embodiment, the leakage current of the electrostatic protection element 100a flowing to the internal short-circuit ring ISR may be reduced via this design.

In addition, in the present embodiment, the overlap area of the gate electrode G and the source/drain electrode SD1 and the overlap area of the gate electrode G and the source/drain electrode SD2 are at least partially overlapped with the semiconductor layer, but the disclosure is not limited thereto.

Referring to FIG. 2B, the main difference between an electrostatic protection device 100b of the present embodiment and the electrostatic protection device 100a is that a length L1b is substantially equal to a length L2b, and a width W1b is greater than a width W2b.

Referring to FIG. 2C, the main difference between an electrostatic protection device 100c of the present embodiment and the electrostatic protection device 100a is that a length L1c is substantially equal to a length L2c, and a width W1c is greater than a width W2c.

Referring to FIG. 2D, the main difference between an electrostatic protection device 100d of the present embodiment and the electrostatic protection device 100a is that a length L1d is greater than a length L2d, and a width W1d is substantially equal to a width W2d.

Accordingly, in the electrostatic protection element 100b, the electrostatic protection element 100c, and the electrostatic protection element 100d shown in FIG. 2B to FIG. 2D respectively, the overlap area of the gate electrode G and the source/drain electrode SD1 in the normal direction z of the active area AA is greater than the overlap area of the gate electrode G and the source/drain electrode SD2 in the normal direction z of the active area AA. This design may reduce the leakage current of the electrostatic protection element 100b, the electrostatic protection element 100c, and the electrostatic protection element 100d flowing to the internal short-circuit ring ISR.

Referring to FIG. 2E, the main differences between an electrostatic protection element 100e of the present embodiment and the electrostatic protection element 100d are: (1) the source/drain electrode SD1 has a pattern protruded in the direction d1, and the overlap area thereof with the gate electrode G includes a plurality of rectangular patterns arranged in the direction d2; (2) in the overlap area of the protruding pattern and the gate electrode G, a length L1e1 is substantially equal to a length L2e and a width W1e1 is substantially equal to a width W2e.

In the present embodiment, although the length L1e1 is substantially equal to the length L2e and the width W1e1 is substantially equal to the width W2e, the source/drain electrode SD1 further includes two patterns arranged in the direction d2. In other words, the source/drain electrode SD1 further includes two overlap areas of a length L1e2 and a width W1e2.

Please refer to FIG. 2F. The main differences between an electrostatic protection element 100f of the present embodiment and the electrostatic protection element 100e are: (1) the source/drain electrode SD1 has a positive E-type pattern in the normal direction z of the active area AA, and the source/drain electrode SD2 has an inverted E-type pattern in the normal direction z of the active area AA; (2) in the overlap area of the protruding pattern and the gate electrode G, a length L1f1 is substantially equal to a length L2f1 and a width W1f1 is substantially equal to a width W2f1, but a length L1f2 is greater than a length L2f2 and a width W1f2 is substantially equal to a width W2f2.

Please refer to FIG. 2G. The main differences between an electrostatic protection element 100g of the present embodiment and the electrostatic protection element 100e are: (1) the source/drain electrode SD1 has a positive E-type pattern in the normal direction z of the active area AA, and the source/drain electrode SD2 has an inverted E-type pattern in the normal direction z of the active area AA; (2) in the overlap area of the protruding pattern and the gate electrode G, a length L1g1 is substantially equal to a length L2g1 and a width W1g1 is substantially equal to a width W2g1, but a length L1g2 is greater than a length L2g2 and a width W1g2 is substantially equal to a width W2g2.

Accordingly, in the electrostatic protection element 100e, the electrostatic protection element 100f, and the electrostatic protection element 100g shown in FIG. 2E to FIG. 2G respectively, the overlap area of the gate electrode G and the source/drain electrode SD1 in the normal direction z of the active area AA is greater than the overlap area of the gate electrode G and the source/drain electrode SD2 in the normal direction z of the active area AA. This design may reduce the leakage current of the electrostatic protection element 100e, the electrostatic protection element 100f, and the electrostatic protection element 100g flowing to the internal short-circuit ring ISR.

Referring to FIG. 2H, the main difference between an electrostatic protection device 100h of the present embodiment and the electrostatic protection device 100b is that a length L1h is greater than a length L2h, and a width W1h is substantially equal to a width W2h.

Referring to FIG. 2I, the main difference between an electrostatic protection device 100i of the present embodiment and the electrostatic protection device 100d is that a length L1i is greater than a length L2i, and a width W1i is greater than a width W2i.

Referring to FIG. 2J, the main difference between an electrostatic protection device 100j of the present embodiment and the electrostatic protection device 100d is that a length L1j is greater than a length L2j, and a width W1j is greater than a width W2j.

Referring to FIG. 2K, the main difference between an electrostatic protection device 100k of the present embodiment and the electrostatic protection device 100d is that a length L1k is greater than a length L2k, and a width W1k is substantially equal to a width W2k.

Accordingly, in the electrostatic protection element 100h, the electrostatic protection element 100i, the electrostatic protection element 100j, and the electrostatic protection element 100k shown in FIG. 2H to FIG. 2K, respectively, the overlap area of the gate electrode G and the source/drain electrode SD1 in the normal direction z of the active area AA is greater than the overlap area of the gate electrode G and the source/drain electrode SD2 in the normal direction z of the active area AA. This design may reduce the leakage current of the electrostatic protection element 100h, the electrostatic protection element 100i, the electrostatic protection element 100j, and the electrostatic protection element 100k flowing to the internal short-circuit ring ISR.

Please refer to FIG. 2L. The main difference between an electrostatic protection element 100l of the present embodiment and the electrostatic protection element 100f is that the electrostatic protection element 100l of the present embodiment is a bottom-gate thin-film transistor having an additional insulating layer (not shown) between the source/drain electrode SD1 and the semiconductor layer SE and between the source/drain electrode SD2 and the semiconductor layer SE. Accordingly, the source/drain electrode SD1 is electrically connected to the semiconductor layer SE via a through hole h1, and the source/drain electrode SD2 is electrically connected to the semiconductor layer SE via a through hole h2. In the present embodiment, the through hole h1 and the through hole h2 are overlapped with the gate electrode G in the normal direction z of the active area AA, but the disclosure is not limited thereto.

Please refer to FIG. 2M. The main difference between an electrostatic protection element 100m of the present embodiment and the electrostatic protection element 100g is that the electrostatic protection element 100m of the present embodiment is a bottom-gate thin-film transistor having an additional insulating layer (not shown) between the source/drain electrode SD1 and the semiconductor layer SE and between the source/drain electrode SD2 and the semiconductor layer SE. For the description of the above, reference may be made to the above embodiments, which is not described in detail here.

Please refer to FIG. 2N. The main difference between an electrostatic protection element 100n of the present embodiment and the electrostatic protection element 100h is that the electrostatic protection element 100n of the present embodiment is a bottom-gate thin-film transistor having an additional insulating layer (not shown) between the source/drain electrode SD1 and the semiconductor layer SE and between the source/drain electrode SD2 and the semiconductor layer SE. For the description of the above, reference may be made to the above embodiments, which is not described in detail here.

Please refer to FIG. 2O. The main difference between an electrostatic protection element 100o of the present embodiment and the electrostatic protection element 100i is that the electrostatic protection element 100o of the present embodiment is a bottom-gate thin-film transistor having an additional insulating layer (not shown) between the source/drain electrode SD1 and the semiconductor layer SE and between the source/drain electrode SD2 and the semiconductor layer SE. For the description of the above, reference may be made to the above embodiments, which is not described in detail here.

Please refer to FIG. 2P. The main difference between an electrostatic protection element 100p of the present embodiment and the electrostatic protection element 100j is that the electrostatic protection element 100p of the present embodiment is a bottom-gate thin-film transistor having an additional insulating layer (not shown) between the source/drain electrode SD1 and the semiconductor layer SE and between the source/drain electrode SD2 and the semiconductor layer SE. For the description of the above, reference may be made to the above embodiments, which is not described in detail here.

Please refer to FIG. 2Q. The main difference between an electrostatic protection element 100q of the present embodiment and the electrostatic protection element 100k is that the electrostatic protection element 100q of the present embodiment is a bottom-gate thin-film transistor having an additional insulating layer (not shown) between the source/drain electrode SD1 and the semiconductor layer SE and between the source/drain electrode SD2 and the semiconductor layer SE. For the description of the above, reference may be made to the above embodiments, which is not described in detail here.

Accordingly, in the electrostatic protection element 1001, the electrostatic protection element 100m, the electrostatic protection element 100n, the electrostatic protection element 100o, the electrostatic protection element 100p, and the electrostatic protection element 100q shown in FIG. 2L to FIG. 2Q, respectively, the overlap area of the gate electrode G and the source/drain electrode SD1 in the normal direction z of the active area AA is greater than the overlap area of the gate electrode G and the source/drain electrode SD2 in the normal direction z of the active area AA. This design may reduce the leakage current of the electrostatic protection element 1001, the electrostatic protection element 100m, the electrostatic protection element 100n, the electrostatic protection element 100o, the electrostatic protection element 100p, and the electrostatic protection element 100q flowing to the internal short-circuit ring ISR.

Please refer to FIG. 2R. The main differences between an electrostatic protection element 100r of the present embodiment and the electrostatic protection element 100l are: (1) the electrostatic protection element 100r of the present embodiment is a top-gate thin-film transistor; (2) the through hole h1 and the through hole h2 are not overlapped with the gate electrode G in the normal direction z of the active area AA; (3) the source/drain electrode SD1 has two patterns protruded in the direction d1, and the source/drain electrode SD2 has two patterns protruded in the direction opposite to the direction d1.

In the present embodiment, in the overlap area of the protruding pattern and the gate electrode G, a length L1r is greater than a length L2r, and a width W1r is substantially equal to a width W2r.

In addition, in the present embodiment, the overlap area of the gate electrode G and the source/drain electrode SD1 and the overlap area of the gate electrode G and the source/drain electrode SD2 are not overlapped with the semiconductor layer, but the disclosure is not limited thereto.

Referring to FIG. 2S, the main difference between an electrostatic protection device 100s of the present embodiment and the electrostatic protection device 100r is that a length L1s is substantially equal to a length L2s, and a width W1s is greater than a width W2s.

Referring to FIG. 2T, the main difference between an electrostatic protection device 100t of the present embodiment and the electrostatic protection device 100r is that a length L1t is greater than a length L2t, and a width W1t is greater than a width W2t.

Accordingly, in the electrostatic protection element 100r, the electrostatic protection element 100s, and the electrostatic protection element 100t shown in FIG. 2R to FIG. 2T respectively, the overlap area of the gate electrode G and the source/drain electrode SD1 in the normal direction z of the active area AA is greater than the overlap area of the gate electrode G and the source/drain electrode SD2 in the normal direction z of the active area AA. This design may reduce the leakage current of the electrostatic protection element 100r, the electrostatic protection element 100s, and the electrostatic protection element 100t flowing to the internal short-circuit ring ISR.

Based on the above, in the electronic devices provided in some embodiments of the disclosure, the parasitic capacitance between the gate electrode and the source/drain electrodes coupled to the internal short-circuit ring is designed to be greater than the parasitic capacitance between the gate electrode and the source/drain electrodes coupled to the scan line. Via this design, when an operating voltage is applied to a specific scan line, the voltage of the gate electrode is relatively close to the voltage applied to the internal short-circuit ring, thereby reducing the leakage current of the electrostatic protection element flowing to the internal short-circuit ring, thereby improving the reliability of the electronic device provided by some embodiments of the disclosure.

What is claimed is:

1. An electronic device, comprising:
a scan line;
an active element disposed in an active area and electrically connected to the scan line;
an internal short-circuit ring disposed in a peripheral area and surrounding the active area; and
an electrostatic protection element disposed in the peripheral area and electrically connected to the internal short-circuit ring and the scan line,
wherein the electrostatic protection element is a transistor and comprises a gate electrode, a first source/drain electrode, a second source/drain electrode, and a semiconductor layer, the gate electrode is in a floating state, the first source/drain electrode is coupled to the internal short-circuit ring, and the second source/drain electrode is coupled to the scan line,
wherein a first parasitic capacitance between the gate electrode and the first source/drain electrode is greater than a second parasitic capacitance between the gate electrode and the second source/drain electrode.

2. The electronic device of claim 1, wherein a first overlap area of the gate electrode and the first source/drain electrode in a normal direction of the active area is greater than a second overlap area of the gate electrode and the second source/drain electrode in the normal direction of the active area.

3. The electronic device of claim 2, wherein the first overlap area and the second overlap area are rectangular patterns in the normal direction of the active area, and a length of the first overlap area in a first direction is greater than a length of the second overlap area in the first direction.

4. The electronic device of claim 3, wherein a width of the first overlap area in a second direction is equal to a width of the second overlap area in the second direction.

5. The electronic device of claim 3, wherein a width of the first overlap area in a second direction is greater than a width of the second overlap area in the second direction.

6. The electronic device of claim 2, wherein the first overlap area and the second overlap area are rectangular patterns in the normal direction of the active area, and a width of the first overlap area in a second direction is greater than a width of the second overlap area in the second direction.

7. The electronic device of claim 6, wherein a length of the first overlap area in a first direction is equal to a length of the second overlap area in the first direction.

8. The electronic device of claim 6, wherein a length of the first overlap area in a first direction is greater than a length of the second overlap area in the first direction.

9. The electronic device of claim 2, wherein the first overlap area comprises a plurality of rectangular patterns arranged in a second direction.

10. The electronic device of claim 2, wherein the second overlap area comprises a plurality of rectangular patterns arranged in a second direction.

11. The electronic device of claim 2, wherein the first overlap area and the second overlap area are at least partially overlapped with the semiconductor layer in the normal direction of the active area.

12. The electronic device of claim 2, wherein the first overlap area and the second overlap area are not overlapped with the semiconductor layer in the normal direction of the active area.

13. The electronic device of claim 1, wherein the first source/drain electrode is electrically connected to the semiconductor layer via a first through hole, and the second source/drain electrode is electrically connected to the semiconductor layer via a second through hole, wherein the first through hole and the second through hole are not overlapped with the gate electrode in the normal direction of the active area.

14. The electronic device of claim 1, wherein the first parasitic capacitance and the second parasitic capacitance satisfy a following inequality:
1<C1/C2<4,
wherein C1 is the first parasitic capacitance, and C2 is the second parasitic capacitance.

15. The electronic device of claim 14, wherein 1.5<C1/C2<2.5.

16. The electronic device of claim 2, wherein the first source/drain electrode has a positive E-type pattern in a normal direction of the active area, and the second source/drain electrode has an inverted E-type pattern in the normal direction of the active area.

17. The electronic device of claim 1, wherein an insulating layer is further disposed between the first source/drain electrode and the semiconductor layer and between the second source/drain electrode and the semiconductor layer.

18. The electronic device of claim 1, wherein the electrostatic protection element is a bottom-gate thin-film transistor.

19. The electronic device of claim 1, wherein the electrostatic protection element is a top-gate thin-film transistor.

20. The electronic device of claim 1, further comprising a gate driving circuit, wherein the gate driving circuit is disposed in the peripheral area and electrically connected to the scan line.
